(19) United States
(12) Patent Application Publication
(10) Pub. No.: US 2026/0215183 A1
(43) Pub. Date: Jul. 23, 2026

(54) CAVITY CONTACT FORMATION USING PLASMA DOPING PROCESS

(71) Applicant: Applied Materials, Inc., Santa Clara, CA (US)

(72) Inventors: Yan Zhang, Westford, MA (US); Vikram M. Bhosle, North Reading, MA (US); Shi You, San Jose, CA (US); Deven Raj Mittal, Middleton, MA (US); Sony Varghese, Manchester, MA (US); Kyu-Ha Shim, Andover, MA (US)

(73) Assignee: Applied Materials, Inc., Santa Clara, CA (US)

(21) Appl. No.: 19/034,794

(22) Filed: Jan. 23, 2025

(51) Int. Cl. H01L 21/223; H01L 21/265; H01L 21/324; H10D 30/01; H10D 62/00

(52) U.S. Cl. CPC H10P 32/1204; H10D 30/0195; H10D 62/01; H10P 30/20; H10P 95/90

(57) ABSTRACT

Approaches herein relate to devices and methods for forming cavity contacts using a plasma doping process. One method may include forming a plurality of alternating first layers and second layers, and forming a source/drain epitaxial material within a trench of the plurality of alternating first layers and second layers. The method may further include forming a cavity in source/drain epitaxial material, and performing a plasma doping process to form a doped area in the source/drain epitaxial material.

### FIELD OF THE DISCLOSURE

The present embodiments relate to semiconductor device patterning, and more particularly, to devices and methods for forming cavity contacts using a plasma doping process.

### BACKGROUND OF THE DISCLOSURE

As integrated circuit (IC) technologies progress towards smaller technology nodes, multigate devices have been used to improve gate control by increasing gate-channel coupling, reducing off-state current, and reducing short-channel effects. A multigate device generally refers to a device having a gate structure, or portion thereof, disposed over more than one side of a channel region. Field effect transistors (FETs) and gate-all-around (GAA) transistors, both also referred to as non-planar transistors, are examples of multigate devices that provide high performance and low leakage applications. The channel region of GAA transistors may be formed from nanowires, nanosheets (NS), or other nanostructures.

To keep reducing resistance (Rc) and improving device performance, a contact area of the device needs to be enlarged. In one approach, a wrap-around-contact scheme can be used to enlarge the contact area. However, this approach requires non-line-of-sight doping, which is challenging. In addition, access resistance from source/drain (S/D) body may limit the total resistance improvement.

In another approach, a cavity, or etch-in-epi contact scheme, can be used to enlarge the contact area, while also reducing the path from contact interface to each NS channel, thus eliminating parasitic resistance. However, the cavity contacts require conformal, shallow sidewall doping with minimal volume buildup to enable continuous scaling. Conventional beamline contact implant is a volumeless and relatively inexpensive process used to dope the cavity conformally through well optimized tilt and rotation angles, energy, dose, etc. However, it is difficult to prevent the ions from being delivered into channel areas, leading to increased risk of mobility degradation, short-channel effects (SCEs) degradation, or both.

On the other hand, current contact epitaxial processes can be used to meet the conformal and shallow doping requirements. However, this process consumes the cavity volume, thus reducing contact area and Rc benefit. As S/D CD continues scaling down, this drawback becomes more problematic.

Accordingly, improved cavity contact processes are needed that are conformal, shallow doping, and volumeless.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a plurality of alternating first layers and second layers, and forming a source/drain epitaxial material within a trench of the plurality of alternating first layers and second layers. The method may further include forming a cavity in source/drain epitaxial material, and performing a plasma doping process to form a doped area in the source/drain epitaxial material.

In another aspect, a method for forming a cavity contact in a semiconductor device may include forming a plurality of alternating first layers and second layers over a base layer, and forming a source/drain epitaxial material within a trench formed through the plurality of alternating first layers and second layers. The method may further include etching the source/drain epitaxial material to form a cavity in source/drain epitaxial material, and performing a plasma doping process following formation of the cavity, wherein the plasma doping process forms a doped area in the source/drain epitaxial material. The method may further include depositing a metal within the cavity, over the doped area in the source/drain epitaxial material.

In yet another aspect, a method may include forming a cavity contact in a semiconductor device by forming a plurality of alternating first layers and second layers over a base layer, and forming a source/drain epitaxial material within the plurality of alternating first layers and second layers. The method may further include forming a trench above the plurality of alternating first layers and second layers, wherein the trench extends to an upper surface of the source/drain epitaxial material, and etching the source/drain epitaxial material to form a cavity in source/drain epitaxial material. The method may further include performing a plasma doping process following formation of the cavity, wherein the plasma doping process impacts an exposed surface of the source/drain epitaxial material to form a doped area in the source/drain epitaxial material, and depositing a metal within the cavity and over the doped area in the source/drain epitaxial material.

### BRIEF DESCRIPTION OF THE DRAWINGS

The accompanying drawings illustrate exemplary approaches of the disclosure, including the practical application of the principles thereof, as follows:

FIG. 1 is a cross-sectional view of a device structure including a source/drain epitaxial layer, according to embodiments of the present disclosure;

FIG. 2 is a cross-sectional view of the device structure following formation of a liner layer within a trench, according to embodiments of the present disclosure;

FIG. 3 is a cross-sectional view of the device structure following formation of a cavity in the source/drain epitaxial layer, according to embodiments of the present disclosure;

FIG. 4 is a cross-sectional view of the device structure during a plasma treatment to form a doped area in the source/drain epitaxial layer, according to embodiments of the present disclosure;

FIG. 5 is a cross-sectional view of the device structure during a variety of additional processes to the source/drain epitaxial layer, according to embodiments of the present disclosure;

FIG. 6 is a cross-sectional view of the device structure following deposition of a metal over the source/drain epitaxial layer, according to embodiments of the present disclosure;

FIG. 7 illustrates a perspective view of an exemplary plasma doping system, according to embodiments of the present disclosure; and

FIG. 8 illustrates a perspective view of an example processing system, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments of the present disclosure are directed to a conformal, shallow-doping plasma doping (PLAD) process for cavity contact formation in a variety of semiconductor devices, such as GAA, complimentary FET, and other logic technologies. Due to the in-situ deposition, which can be etched after a cleaning process, and wide angular distribution of the ions, PLAD can achieve shallow doping with little to no impact on cavity volume. Furthermore, compared to existing contact epitaxial processes, PLAD doping is cost effective.

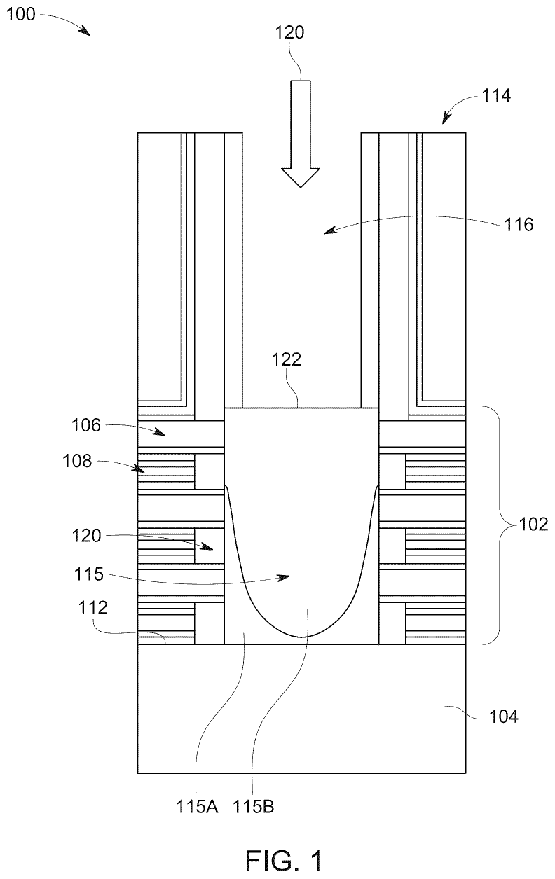

With reference to FIG. 1, an approach for forming a semiconductor device (hereinafter “device”) 100 according to one or more embodiments will be described. Although non-limiting, the device 100 may be a GAA device structure, a vertical GAA device structure, or a horizontal GAA device structure. Alternatively, the device may be a CFET. As shown, the device 100 may include a nanosheet stack 102 including a plurality of alternating first layers 106 and second layers 108 formed over a base layer (e.g., substrate) 104.

The term ‘nanosheet,’ as used herein, refers to a sheet or a layer having nanoscale dimensions. Further, the term ‘nanosheet’ is meant to encompass other nanoscale structures such as nanowires. For instance, ‘nanosheet’ can refer to a nanowire with a larger width, and/or ‘nanowire’ can refer to a nanosheet with a smaller width, and vice versa.

In various embodiments, the plurality of alternating first layers 106 and second layers 108 may include between two (2) and ten (10) first layers 106 and between two (2) and ten (10) second layers 108. A composition of the first layers 106 may be different than a composition of the second layers 108 to achieve etching selectivity and/or different oxidation rates during subsequent processing, for example. In some embodiments, the plurality of alternating first layers 106 and second layers 108 may include different materials, different constituent atomic percentages, different constituent weight percentages, and/or other different characteristics to achieve desired etching selectivity. Although non-limiting, the plurality of alternating first layers 106 and second layers 108 may be epitaxially grown in the depicted interleaving and alternating configuration, layer-by-layer, until a desired number of semiconductor layers is reached.

The device 100 may be processed (e.g., etched) to form a trench, which extends to a top surface 112 of the base layer 104. For example, the nanosheet stack 102 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. Embodiments herein are not limited in this context.

Within the trench a source/drain epitaxial material (hereinafter “S/D epi”) 115 may be formed. In the embodiment shown, the S/D epi 115 may be formed using an epitaxy process such as chemical vapor deposition (CVD) (e.g., vapor phase epitaxy and/or Ultra-High Vacuum CVD), molecular beam epitaxy, other suitable epitaxial growth processes, or combinations thereof, to form the S/D epi 115. The epitaxy process can use gaseous and/or liquid precursors. In some embodiments, the S/D epi 115 may be silicon. In the embodiment shown, the S/D epi 115 may include a first material 115A and a second material 115B, wherein the first and second materials 115A, 115B are the same or different. In yet other embodiments, only a single epitaxial material layer is formed within the trench. Embodiments herein are not limited in this context.

According to an exemplary embodiment, the base layer 104 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the base layer 104 may include a semiconductor material, e.g., silicon (Si), carbon (C), germanium (Ge), silicon germanium (SiGe), germanium tin (GeSn), other semiconductor materials, or any combination thereof. In one or more embodiments, the base layer 104 may include one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

A gate structure 114 (e.g., dummy gate) may also be formed over the first layers 106 and the second layers 108, on opposite sides of a trench 116. The gate structure 114 may include a sacrificial gate having a gate material layer and an interlayer dielectric formed atop the gate material layer. In some embodiments, the gate material layer may be an amorphous silicon (a-Si) or a polysilicon. In some embodiments, the trench 116 may be formed using an etch process 120, which is selective to an upper surface 122 of the S/D epi 115.

In some embodiments, a lateral selective etch may be performed to trim the second layers 108 horizontally (e.g., by a few nm) to form gaps between Si nanosheets. One or more low-k materials may then be used to fill these gaps and form an inner spacer 124.

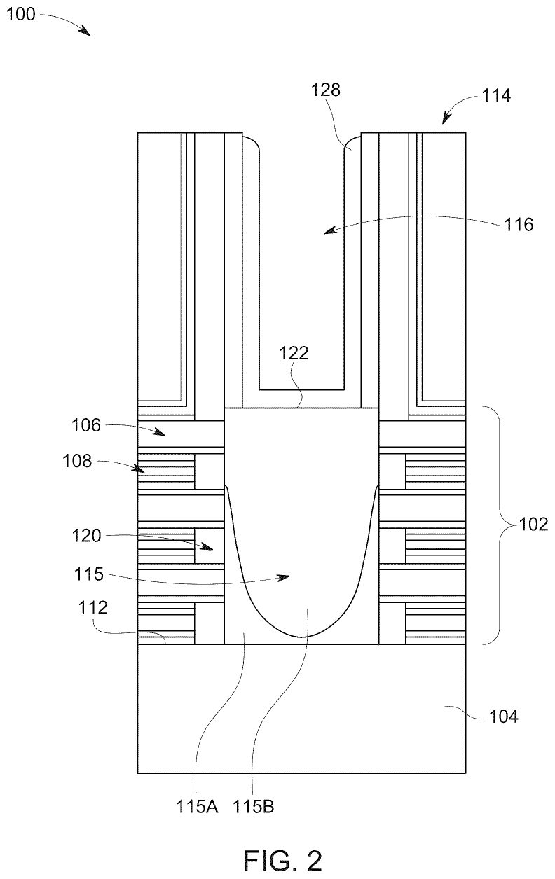

As shown in FIG. 2, an optional liner layer 128 may be formed within the trench 116, including directly atop the upper surface 122 of the S/D epi 115. In some embodiments the liner layer 128 may be a dielectric material (e.g., silicon, oxygen, nitrogen, or carbon), which is conformally deposited along the exposed surfaces of the trench 116. The liner layer 128 may include different materials in other embodiments.

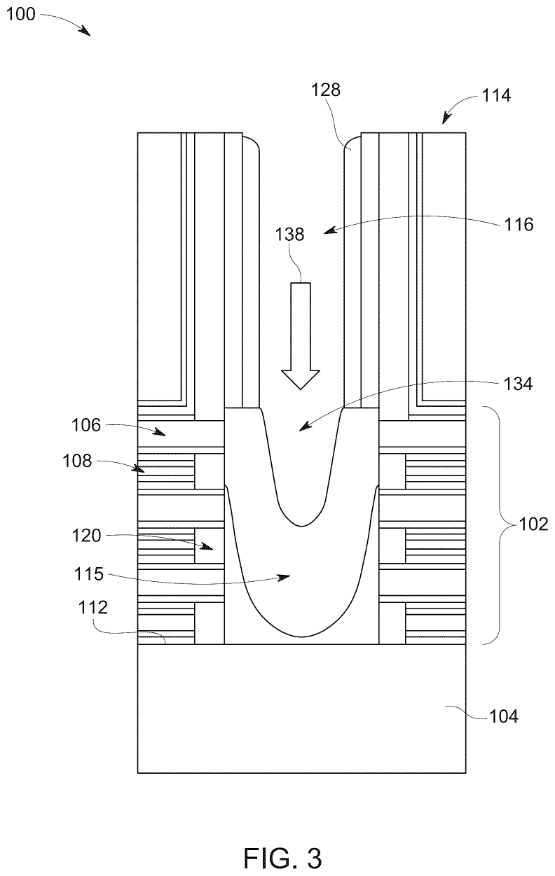

As shown in FIG. 3, a recess or cavity 134 may be formed in the S/D epi 115. In some embodiments, the cavity 134 may be formed using a dry/anisotropically etch 138 within the trench 116. The etch 138 removes a portion of the liner layer 128 and a portion of the S/D epi 115.

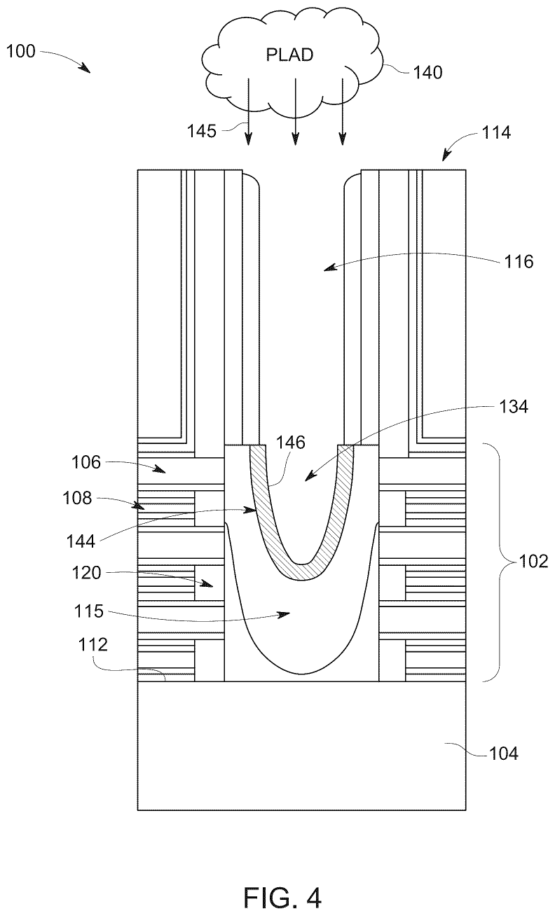

In some embodiments, as shown in FIG. 4, the S/D epi 115 may be doped using an in-situ treatment 140 to form a doped area 144 in the S/D epi 115. More specifically, the treatment 140 may be a plasma treatment, such as a plasma doping (PLAD) or decoupled plasma treatment (DPX), which impacts an exposed surface 146 of the S/D epi 115 within the cavity 134. One or more implant processes may be performed whereby ions 145 are delivered through the trench 116 and the cavity 134. Although non-limiting, the ions 145 may include p-type or n-type species depending on whether the nanosheet stack 102 is nFET or pFET. For example, nFET species may include arsenic, phosphorous, or antimony, together with a phosphine (PH3) or arsenic-containing (AsHx) precursor. Meanwhile, pFET species may include boron, indium, or gallium, together with a diborane (B2H6) precursor. It will be appreciated that other species and/or precursors are possible in alternative embodiments.

In various embodiments, the PLAD treatment 140 is performed at room temperature (e.g., 15-30° C.) or greater. In various embodiments, the implant process may be delivered at a substantially horizontal angle relative to the nanosheet stack 102, as shown, and/or vertically. As such, the ions 145 may simultaneously impact the exposed surface 146 of the S/D epi 115 to form the doped area 144. Although non-limiting, the implant process may be constant or variable. Advantageously, the PLAD treatment 140 is volumeless, i.e., little to no material is built-up along the exposed surface 146 of the S/D epi 115, and it provides a shallow doping with little risk of SCEs degradation.

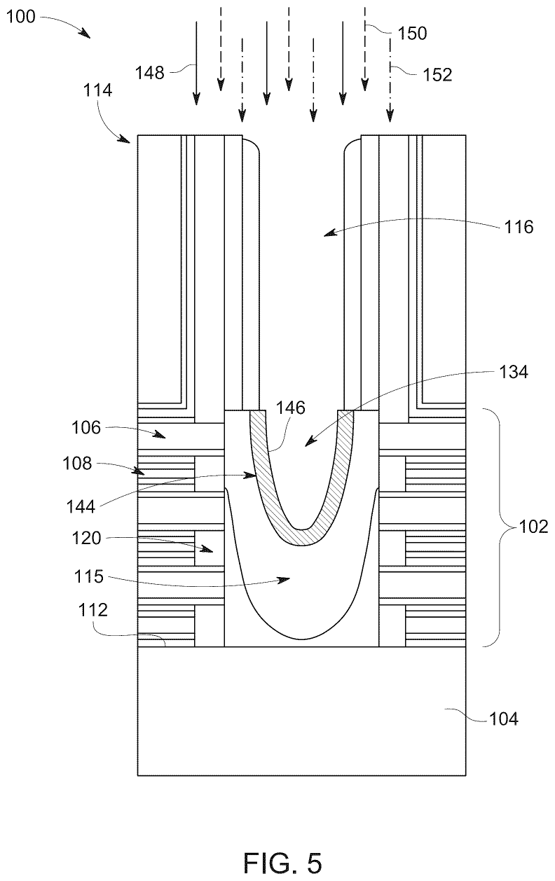

As shown in FIG. 5, an optional thermal process (e.g., a contact anneal) 148 may be performed after the PLAD treatment 140 to activate the dopants of the doped area 144. In some embodiments, the thermal process 148 may be a dynamic surface anneal (DSA) performed at a temperature of approximately 850° C., e.g., when a frontside contact process is being performed. As a result of the implantation and thermal processes, Rc may be minimized for the sidewalls of the trench containing the S/D epi 115.

In other embodiments, the thermal treatment to activate the dopants may be achieved via one or more subsequent front end of the line (FEOL) thermal processing steps, such as during metal deposition and silicidation. In yet other embodiments, a first thermal treatment may be performed immediately following the plasma treatment process and a second thermal treatment may occur during one or more FEOL processes.

As further shown in FIG. 5, an optional surface clean 150 may be performed following the PLAD treatment 140. In some embodiments, the surface clean 150 is a wet etch and/or photoresist (PR) strip, which impacts the exposed surface 146 of the doped area 144 of the S/D epi 115. The surface clean 150 may be performed to remove undesired deposition of material during the PLAD treatment, thus insuring the volume of material within the cavity 134 is kept to a minimum. In some embodiments, the thermal process 148 may be performed following the surface clean 150.

As still further shown in FIG. 5, an optional pre-amorphization implant (PAI) 152 may be performed before or after the PLAD treatment 140. For example, in the case that the nanosheet stack 102 is part of a pFET, the PAI 152 may be delivered to the S/D epi 115 through the cavity 134. The PAI 152 may be used together with the PLAD treatment 140 in order to better control the placement of ions within S/D epi 115. The PAI 152 may generate an amorphous layer in a previously monocrystalline region of the S/D epi 115, wherein this amorphous layer can suppress channeling of subsequently implanted dopant ions, resulting in a more controlled and predictable dopant profile of the doped area 144. In addition to using pre-amorphized layers for dechanneling dopant implantation, PAI may be used to improve re-crystallization and electrical activation during thermal annealing, or for precision material engineering applications. In various embodiments, a beamline ion implanter or a plasma doping tool may be used to perform the PAI 152.

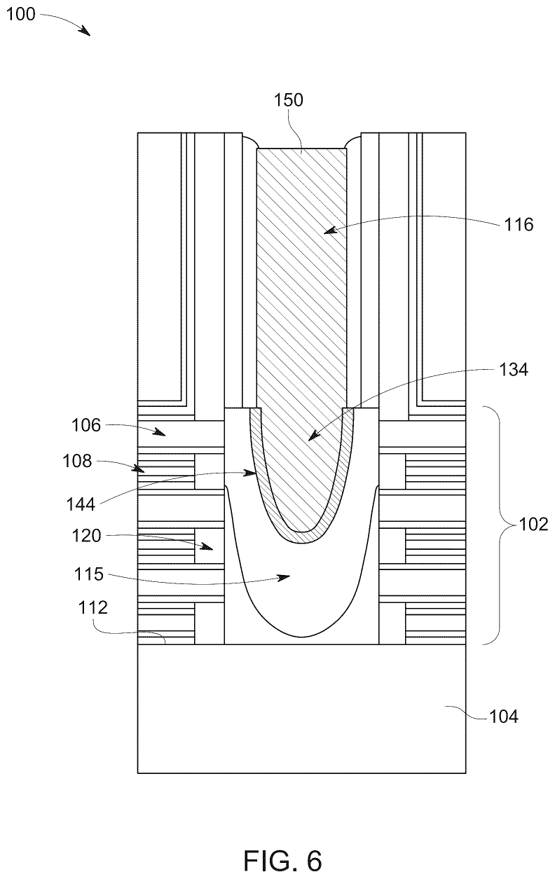

As shown in FIG. 6, a metal deposition and silicidation process may then be performed to form a metal 160 within the trench 116 and the cavity 134. The metal 160 may be deposited directly atop the doped area 144 of the S/D epi 115 to form a cavity contact. As a result of the previously performed dopant and thermal processes, resistance is lower at the interface between the metal 160 and the S/D epi 115. Although non-limiting, the metal 160 may be, or comprise, titanium, titanium nitride, cobalt, tungsten, copper, ruthenium, alloys thereof, or a combination thereof, and may be deposited by CVD, atomic layer deposition (ALD), physical vapor deposition (PVD, or another deposition technique. A dielectric layer (not shown) may then be formed over the metal 160, and processing of the device 100 may continue.

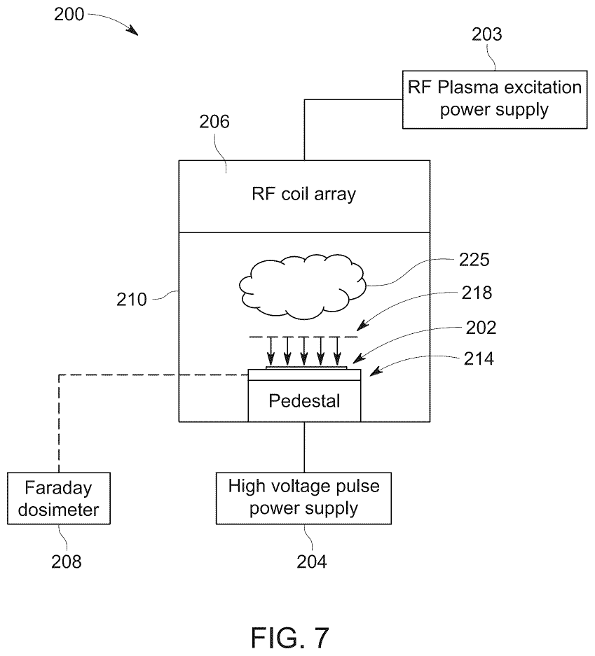

Referring to FIG. 7, an example system 200 (e.g., a PLAD system) operable to provide pulsed RF-excited continuous plasma doping to the device 100 of FIG. 4, will be described. As shown, the system 200 may include a plasma power supply 203, a voltage pulse power supply 204, an RF coil array 206, and a dosimeter 208. Within a plasma chamber 210 is a wafer/substrate 202, which may be the same or similar to the base layer 104 described above. A platen/pedestal 214 may support the wafer 202, and a sheath 218 may be formed above the wafer 202. A temperature of the platen/pedestal 214 may be elevated (e.g., to 500° C. or greater) during plasma doping. The dosimeter 208 may be a Faraday dosimeter or other type of sensor that directly measures the dose of ions received by the wafer 202. Although non-limiting, the dosimeter can be located on the pedestal 214, proximate to the wafer 202.

During use, the plasma power supply 203 and the RF coil array 206 deliver radio frequency excitation to generate a plasma 225 when gaseous species are delivered into the plasma chamber 210. For example, the plasma power supply 203 may be an RF powered inductively coupled power source to generate inductively coupled plasma 225, as known in the art. Gaseous species may be delivered from one or more gas sources (not separately shown) to generate ions of any suitable species, such as boron.

The voltage pulse power supply 204 may generate a bias voltage between the wafer 202 and the plasma chamber 210. As such, when the voltage pulse power supply 204 generates a voltage between the plasma chamber 210 and the substrate 202, a similar, but slightly larger, voltage difference is generated between the plasma 225 and the substrate 202. In one non-limiting example, a 5000 (5 kV) voltage difference established between the plasma chamber 210 and the substrate 202 (or, equivalently, pedestal 214) may generate a voltage difference of approximately 5005 V to 5030 V between the plasma 225 and the substrate 202.

In some embodiments, the voltage pulse power supply 204 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 200 may further include a controller (not shown), to control the pulsing routine applied to the substrate 202, in order to provide the PLAD treatment 140.

According to various embodiments, the plasma 225 may be formed at least in part of ions that constitute an amorphizing species, wherein the amorphizing species may be any suitable ion capable of amorphizing an initially crystalline region of materials, such as the substrate 202. In various non-limiting embodiments, such suitable ions may include boron. When the plasma 225 is present in the plasma chamber 210, the controller may generate a signal for the voltage pulse power supply 204 to apply a pulse routine to the substrate 202, where the pulse routine constitutes a plurality of extraction voltage pulses. As such, when the extraction voltage pulses are applied between the substrate 202 and plasma 225, ions are extracted in pulsed form from the plasma 225, generating a plurality of ion pulses that are directed to the substrate 202.

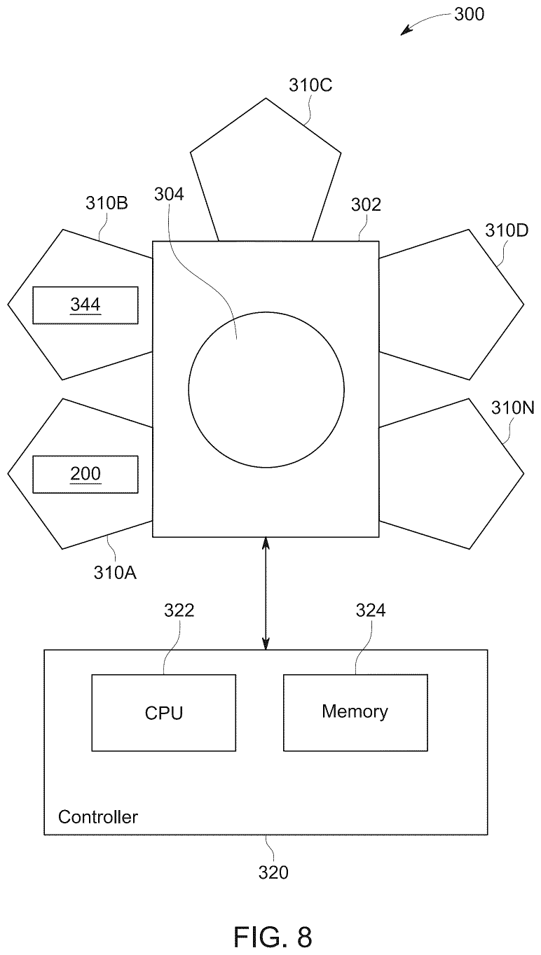

FIG. 8 shows a schematic of another example apparatus/system 300 according to embodiments of the disclosure. In some embodiments, the system 300 may be a cluster tool operable to perform processes necessary to form the device 100 described herein and shown in FIGS. 1-6. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support beamline ion implantation, material deposition, PLAD, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be include the system 200 (e.g., PLAD tool), which is operable to form the doped area 144 in the S/D epi 115, as described herein.

In some embodiments, processing chamber 310B may include a beam-line ion processing apparatus 344 including an ion source for generating ions. For example, the ion source may provide an ion beam treatment, such as the PAI 152 demonstrated in FIG. 5.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processing unit 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
forming a plurality of alternating first layers and second layers;
forming a source/drain epitaxial material within a trench of the plurality of alternating first layers and second layers;
forming a cavity in source/drain epitaxial material; and
performing a plasma doping process to form a doped area in the source/drain epitaxial material.

2. The method of claim 1, further comprising performing a thermal process following the plasma doping process.

3. The method of claim 2, wherein the thermal process is an anneal.

4. The method of claim 1, further comprising depositing a metal within the cavity, over the doped area in the source/drain epitaxial material.

5. The method of claim 1, further comprising forming an inner spacer layer along the plurality of alternating first layers and second layers.

6. The method of claim 1, further comprising:
forming a liner layer within the trench; and
etching the liner layer and the source/drain epitaxial material to form the cavity in the source/drain epitaxial material.

7. The method of claim 1, further comprising performing a surface clean to the source/drain epitaxial material following the plasma doping process.

8. The method of claim 1, further comprising performing a pre-amorphization implant to the source/drain epitaxial material.

9. A method for forming a cavity contact in a semiconductor device, the method comprising:
forming a plurality of alternating first layers and second layers over a base layer;
forming a source/drain epitaxial material within a trench formed through the plurality of alternating first layers and second layers;
etching the source/drain epitaxial material to form a cavity in source/drain epitaxial material;
performing a plasma doping process following formation of the cavity, wherein the plasma doping process forms a doped area in the source/drain epitaxial material; and
depositing a metal within the cavity, over the doped area in the source/drain epitaxial material.

10. The method of claim 9, further comprising performing a thermal process following the plasma doping process.

11. The method of claim 10, wherein the thermal process is an anneal.

12. The method of claim 9, further comprising forming an inner spacer layer along the plurality of alternating first layers and second layers.

13. The method of claim 9, further comprising:
forming a liner layer within the trench; and
etching the liner layer and the source/drain epitaxial material to form the cavity in the source/drain epitaxial material.

14. The method of claim 9, further comprising performing a surface clean to the source/drain epitaxial material following the plasma doping process.

15. The method of claim 9, further comprising performing a pre-amorphization implant to the source/drain epitaxial material.

16. A method for forming a cavity contact in a semiconductor device, the method comprising:
forming a plurality of alternating first layers and second layers over a base layer;
forming a source/drain epitaxial material within the plurality of alternating first layers and second layers;
forming a trench above the plurality of alternating first layers and second layers, wherein the trench extends to an upper surface of the source/drain epitaxial material;
etching the source/drain epitaxial material to form a cavity in source/drain epitaxial material;
performing a plasma doping process following formation of the cavity, wherein the plasma doping process impacts an exposed surface of the source/drain epitaxial material to form a doped area in the source/drain epitaxial material; and
depositing a metal within the cavity and over the doped area in the source/drain epitaxial material.

17. The method of claim 16, further comprising performing a thermal process following the plasma doping process, wherein the thermal process is an anneal or part of a silicidation process.

18. The method of claim 16, further comprising forming an inner spacer layer along the plurality of alternating first layers and second layers.

19. The method of claim 16, further comprising:
forming a liner layer within the trench; and
etching the liner layer and the source/drain epitaxial material to form the cavity in the source/drain epitaxial material.

20. The method of claim 16, further comprising performing a surface clean to the source/drain epitaxial material following the plasma doping process.
